(19) United States
(12) Patent Application Publication
(10) Pub. No.: US 2021/0257322 A1
(43) Pub. Date: Aug. 19, 2021

(54) SEMI-FINISHED PRODUCT OF POWER DEVICE, MANUFACTURING METHOD THEREOF, AND MANUFACTURING METHOD OF POWER DEVICE

(71) Applicant: ACTRON TECHNOLOGY CORPORATION, Taoyuan City (TW)

(72) Inventors: I-Dar Shen, Taoyuan City (TW); Jung-Hsien Lan, Taoyuan City (TW); Te-Pan Wang, Taoyuan City (TW)

(73) Assignee: ACTRON TECHNOLOGY CORPORATION, Taoyuan City (TW)

(21) Appl. No.: 16/907,316

(22) Filed: Jun. 22, 2020

(30) Foreign Application Priority Data
Feb. 13, 2020 (TW) 109104445

(51) Int. Cl. H01L 23/00

(52) U.S. Cl. CPC H01L 24/03; H01L 24/05; H01L 2224/03003; H01L 2224/05563; H01L 2224/03436; H01L 2224/05573

(57) ABSTRACT

A semi-finished product of a power device including a semiconductor chip and a first solder pad is provided. The semiconductor chip has an active surface and a rear surface opposite to the active surface. The first solder pad is positioned and fixed on a center of the semiconductor chip. The first solder pad is sheet-shaped. The semiconductor chip is connected to the first solder pad with the active surface. A size of the first solder pad is smaller than a size of the semiconductor chip to expose a portion of the semiconductor chip. A manufacturing method of the semi-finished product of the power device and a manufacturing method of the power device are also provided.

### CROSS-REFERENCE TO RELATED APPLICATION

This application claims the priority benefit of Taiwan patent application serial no. 109104445, filed on Feb. 13, 2020. The entirety of the above-mentioned patent application is hereby incorporated by reference here and made a part of this specification.

### BACKGROUND

### Technical Field

The disclosure relates to a power device and a manufacturing method thereof, and more particularly to a semi-finished product of a power device, a manufacturing method thereof, and a manufacturing method of the power device.

### Description of Related Art

Power devices may be used in rectifiers, vehicle generators, and high-power module generators. Generally speaking, in terms of the manufacture of the power devices, the solder pads, chips, and electrodes are welded in one goal, so it is easy to cause an offset generated by misalignment between the solder pads, chips, and electrodes, thereby increasing the probability of overflow after the solder pads are welded, which is unable to meet the electrical requirements required by the power devices. Therefore, how to reduce the probability of overflow of the power devices after welding in order to meet the electrical requirements required by the power devices is an important topic urgently in need of solution.

### SUMMARY

The disclosure provides a semi-finished product of a power device, a manufacturing method thereof, and a manufacturing method of the power device, which can reduce the probability of overflow of the power device after welding in order to meet the electrical requirements required by the power device, improve the quality of the power device, and increase the yield of the power device. The power device is, for example, a vehicle rectifier diode apparatus.

A semi-finished product of a power device according to the disclosure includes a semiconductor chip and a first solder pad. The semiconductor chip has an active surface and a rear surface opposite to the active surface. The first solder pad is positioned and fixed on a center of the semiconductor chip. The first solder pad is sheet-shaped. The semiconductor chip is connected to the first solder pad with the active surface. A size of the first solder pad is smaller than a size of the semiconductor chip to expose a portion of the semiconductor chip.

A manufacturing method of a semi-finished product of a power device according to the disclosure at least includes the following steps. A mold is provided, wherein the mold has multiple grooves. A first solder pad is disposed in each of the multiple grooves. A semiconductor chip is disposed on the first solder pad. The first solder pad is positioned on a center of the semiconductor chip. A size of the first solder pad is smaller than a size of the semiconductor chip to expose a portion of the semiconductor chip. The first solder pad is fixed on the center. The mold is removed.

A manufacturing method of a power device according to the disclosure at least includes the following steps. A semi-finished product of the power device, a first electrode, a second electrode, and a second solder pad are provided. The semi-finished product of the power device and the second solder pad are located between the first electrode and the second electrode. The semi-finished product of the power device includes the semiconductor chip and the first solder pad. The first solder pad is positioned and fixed on a center of the semiconductor chip. A size of the first solder pad is smaller than a size of the semiconductor chip to expose a portion of the semiconductor chip. The first electrode, the second electrode, the semi-finished product of the power device, and the second solder pad are welded to form an electrical connection.

In an embodiment of the disclosure, the semiconductor chip has an active surface and a rear surface opposite to the active surface. The semiconductor chip is connected to the first solder pad with the active surface.

Based on the above, the semi-finished product of the power device of the disclosure first positions and fixes the first solder pad on the center of the semiconductor chip, so that an offset of the first solder pad generated by misalignment can be reduced when the first electrode, the second electrode, the semi-finished product of the power device, and the second solder pad are welded, thereby reducing the probability of overflow after the first solder pad is welded in order to meet the electrical requirements required by the power device, especially the high reliability required by the vehicle power device, improve the quality of the power device, and increase the yield of the power device.

To make the aforementioned and other features of the disclosure more comprehensible, several embodiments accompanied with drawings are described in detail as follows.

### BRIEF DESCRIPTION OF THE DRAWINGS

FIG. 1A to FIG. 1C are cross-sectional views of a semi-finished product of a power device according to an embodiment of the disclosure in different stages of a manufacturing process.

FIG. 1D is a top view of the semi-finished product of the power device at the stage of FIG. 1A.

FIG. 2A is a perspective view of a power device according to another embodiment of the disclosure.

FIG. 2B is a cross-sectional view of a portion of the power device according to FIG. 2A.

FIG. 2C is a cross-sectional view of a portion of the power device of FIG. 2B after welding.

FIG. 3A is a perspective view of a power device according to yet another embodiment of the disclosure.

FIG. 3B is a cross-sectional view of a portion of the power device according to FIG. 3A.

FIG. 3C is a cross-sectional view of a portion of the power device of FIG. 3B after welding.

### DETAILED DESCRIPTION OF DISCLOSED EMBODIMENTS

Exemplary embodiments of the disclosure will be fully described below with reference to the drawings, but the disclosure may also be implemented according to many different forms and should not be construed as being limited to the embodiments described herein. In the drawings, in order to be clear, the size and thickness of each region, portion, and layer may not be drawn to actual scale. In order to facilitate understanding, the same elements in the following description will be described with the same reference numerals.

No method described herein is intended to be construed as requiring the steps thereof to be executed in a particular order unless explicitly stated otherwise.

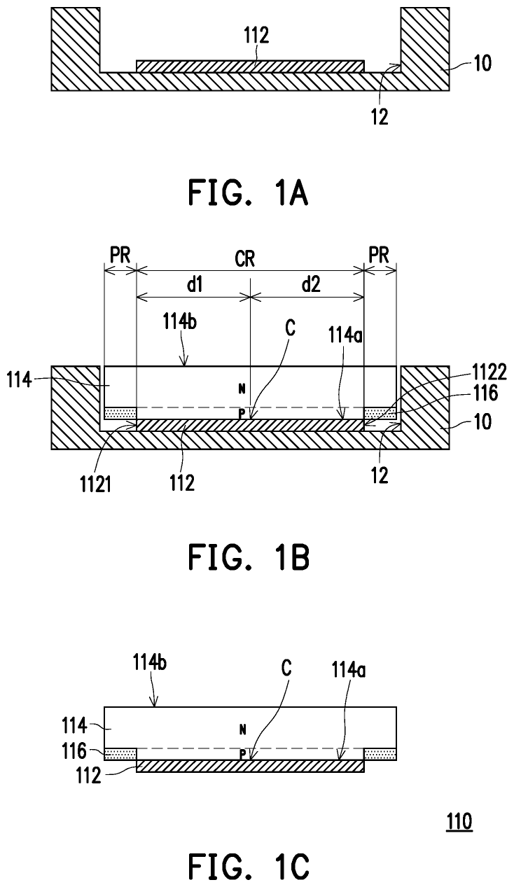

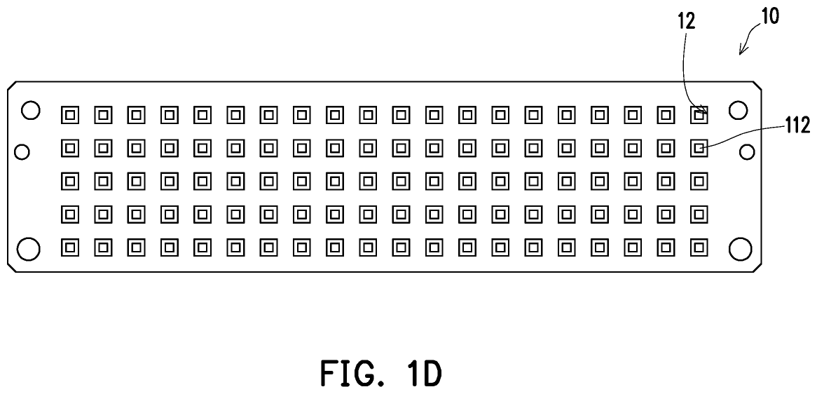

FIG. 1A to FIG. 1C are cross-sectional views of a semi-finished product of a power device according to an embodiment of the disclosure in different stages of a manufacturing process. FIG. 1D is a top view of the semi-finished product of the power device at the stage of FIG. 1A.

In the embodiment, a manufacturing method of a semi-finished product 110 of a power device may include the following steps.

Please refer to FIG. 1A and FIG. 1D at the same time. A mold 10 is provided. The mold 10 has multiple grooves 12. The multiple grooves 12 may be arranged in an array on the mold 10. The material of mold 10 is, for example, an aluminum alloy. The method of forming the groove 12 is, for example, by a computer numerical control (CNC) milling machine. It should be noted that the multiple grooves 12 on the mold 10 of FIG. 1D are only schematically illustrated, and the positions, quantity, distribution range, specific internal structures, forming methods, etc. of the multiple grooves 12 may be changed according to requirements. As long as the groove 12 of the mold 10 can accommodate subsequent first solder pad 112 and semiconductor chip 114 to be welded, all of the same belong to the protection scope of the disclosure.

Please continue to refer to FIG. 1A and FIG. 1D. The first solder pad 112 is disposed in the groove 12. For example, each groove 12 may accommodate one first solder pad 112. The groove 12 and the first solder pad 112 may be disposed one-to-one. The shape of the first solder pad 112 may be rectangular, circular, or hexagonal, but the disclosure is not limited thereto. The shape of the first solder pad 112 may be determined according to actual design requirements. The first solder pad 112 may be a metallic material. For example, the material of the first solder pad 112 is, for example, tin. In addition, in a top view, the groove 12 and the first solder pad 112 may have similar shapes. As shown in FIG. 1D, in a top view, the groove 12 and the first solder pad 112 may both have rectangular shapes, but the disclosure is not limited thereto. In other unshown embodiments, in a top view, the groove 12 and the first solder pad 112 may also have different shapes.

Please refer to FIG. 1B. The semiconductor chip 114 is disposed on the first solder pad 112 of the groove 12. The first solder pad 112 is positioned and fixed on the semiconductor chip 114. On the other hand, a size of the first solder pad 112 may be smaller than a size of the semiconductor chip 114 to expose a portion of the semiconductor chip 114. In one embodiment, a ratio of the surface area, joined by the semiconductor chip 114 and the first solder pad 112, occupied by the first solder pad 112 is, for example, between 50% and 70%, such as 60%, so as to achieve the effect of controlling overflow of the first solder pad 112 better, but the disclosure is not limited thereto.

In the embodiment, each groove 12 may accommodate one first solder pad 112 and one semiconductor chip 114. The first solder pad 112 is located between a bottom of the groove 12 and the semiconductor chip 114. In other words, the first solder pad 112 and the semiconductor chip 114 are sequentially stacked on the bottom of the groove 12. There is a gap in a stacking direction between the semiconductor chip 114 and the groove 12. With the use of the mold 10, multiple first solder pads 112 and multiple semiconductor chips 114 may be respectively and correspondingly positioned and fixed together in one goal. Therefore, the process can be simplified to improve the manufacturing efficiency of the semi-finished product 110 of the power device and increase the alignment accuracy.

In the embodiment, the first solder pad 112 may be positioned and fixed on a center C of the semiconductor chip 114. Here, a distance d1 between a first edge 1121 of the first solder pad 112 and the center C and a distance d2 between a second edge 1122 of the first solder pad 112 and the center C may be substantially equal. In other words, the semiconductor chip 114 may have a center region CR and a peripheral region PR surrounding the center region CR, and the first solder pad 112 is positioned and fixed on the center region CR. The first edge 1121 and the second edge 1122 of the semiconductor chip 114 may be substantially aligned with the edge of the center region CR, and the peripheral region PR has a uniform width, but the disclosure is not limited thereto. In one embodiment, the first solder pad 112 and the semiconductor chip 114 may be sintered to position and fix the first solder pad 112 on the center C, but the disclosure is not limited thereto.

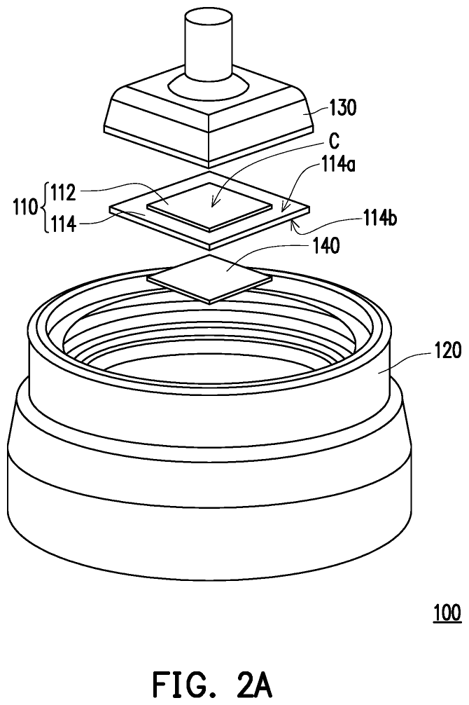

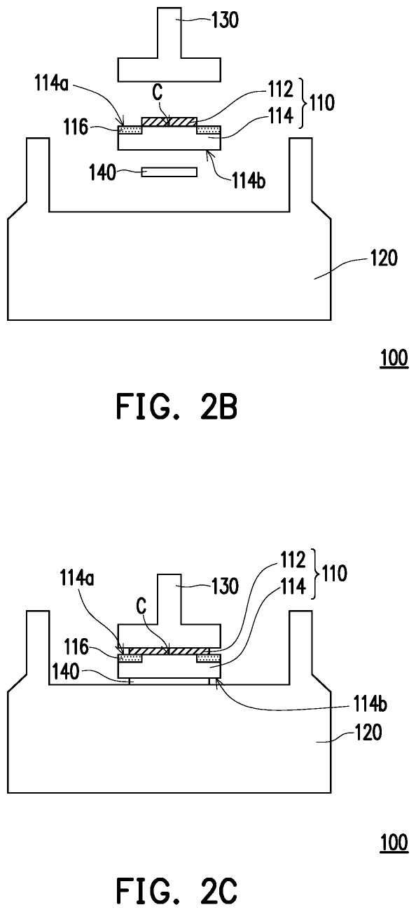

Since the semi-finished product 110 of the power device of the embodiment first positions and fixes the first solder pad 112 on the center C of the semiconductor chip 114, an offset generated by misalignment between the first solder pad 112, the semiconductor chip 114, and electrodes (first electrode 120 and second electrode 130) can be reduced during the subsequent manufacturing process of a power device 100 (as shown in FIG. 2A to FIG. 2C), thereby reducing the probability of overflow after the first solder pad 112 is welded in order to meet the electrical requirements required by the power device 100, improve the quality of the power device 100, and increase the yield of the power device 100. For example, the yield of the power device 100 may be increased by about 20% to 30%.

In the embodiment, the semiconductor chip 114 has an active surface 114a (for example, a p-type end) and a rear surface 114b (for example, an n-type end) opposite to the active surface 114a, wherein the semiconductor chip 114 may be connected to the first solder pad 112 with the active surface 114a. In the embodiment, a ratio of the surface area of the active surface 114a occupied by the first solder pad 112 is between 50% and 70%, but the disclosure is not limited thereto. In the subsequent manufacturing process of the power device 100, the active surface 114a and the rear surface 114b of the semiconductor chip 114 both need to be disposed with solder pads, such that the semiconductor chip 114 may be electrically connected to the corresponding electrode. Also, comparing the solder pad on the active surface 114a of the semiconductor chip 114 with the solder pad on the rear surface 114b of the semiconductor chip 114, it is easier for the solder pad on the active surface 114a of the semiconductor chip 114 after welding to cause the two ends of the semiconductor chip 114 to be conductive and short-circuited if overflow beyond the edge of the active surface 114a happens. Therefore, in order to prevent the situation of overflow causing short-circuit after the solder pad on the active surface 114a of the semiconductor chip 114 is welded from happening, the semi-finished product 110 of the power device of the disclosure may first position and fix the first solder pad 112 on the active surface 114a of the semiconductor chip 114 before performing the subsequent process, so as to improve the quality of the power device 100 and the yield of the power device 100. However, the disclosure is not limited thereto. In an unshown embodiment, the semiconductor chip 114 may also be connected to the second solder pad 140 of the semi-finished product 110 of the power device with the rear surface 114b at the same time, that is, after the active surface 114a and the rear surface 114b of the semiconductor chip 114 respectively connect to the first solder pad 112 and the second solder pad 140 to form the semi-finished product 110, the second electrode 130 and the first electrode 120 are joined.

Please continue to refer to FIG. 1B. In the embodiment, the semiconductor chip 114 may further include an insulating portion 116 and the insulating portion 116 surrounds the first solder pad 112. For example, the insulating portion 116 may be located on the active surface 114a of the semiconductor chip 114 and the first solder pad 112 is located between the insulating portion 116. The first solder pad 112 and the insulating portion 116 may not be in contact, as shown in FIG. 1B, in other words, an orthographic projection of the insulating portion 116 on a bottom of the mold 10 and an orthographic projection of the first solder pad 112 on the bottom of the mold 10 do not overlap. However, the disclosure is not limited thereto. In an unshown embodiment, the first solder pad 112 may contact a portion of the insulating portion 116, in other words, the orthographic projection of the insulating portion 116 on the bottom of the mold 10 and the orthographic projection of the first solder pad 112 on the bottom of the mold 10 may partially overlap.

Please refer to FIG. 1C. After the semiconductor chip 114 is disposed on the first solder pad 112, the mold 10 is removed. After the above process, the production of the semi-finished product 110 of the power device according to the embodiment may be substantially completed. It should be noted that the disclosure does not limit the manufacturing method of the semi-finished product 110 of the power device. As long as the semi-finished product 110 of the power device at least has one solder pad (for example, the first solder pad 112) positioned and fixed on the center C of any surface (for example, the active surface 114a or the rear surface 114b) of the semiconductor chip 114, all of the same belong to the protection scope of the disclosure.

It must be noted here that the following embodiments continue to use the reference numerals and some contents of the above embodiment, wherein the same or similar reference numerals are used to indicate the same or similar elements and descriptions of the same technical content are omitted. Refer to the foregoing embodiment for the descriptions of the omitted parts, which will not be reiterated in the following embodiments.

FIG. 2A is a perspective view of a power device according to another embodiment of the disclosure. FIG. 2B is a cross-sectional view of a portion of the power device according to FIG. 2A. FIG. 2C is a cross-sectional view of a portion of the power device of FIG. 2B after welding.

In the embodiment, a power device 100 is, for example, a rectifier diode applied to a vehicle generator, in particular a press-fit rectifier diode, which is configured to rectify AC power into DC power to be transmitted to various electrical apparatuses and batteries in a vehicle system. A first electrode 120 of the power device 100 is, for example, a base electrode of the rectifier diode apparatus. A second electrode 130 is, for example, a lead electrode of the rectifier diode apparatus. The manufacturing method of the power device 100 may include the following steps.

Please refer to FIG. 2A and FIG. 2B at the same time. A semi-finished product 110 of the power device 100, the first electrode 120, the second electrode 130, and a second solder pad 140 are provided. The semi-finished product 110 of the power device 100 and the second solder pad 140 are located between the first electrode 120 and the second electrode 130. The semi-finished product 110 of the power device includes the first solder pad 112 and the semiconductor chip 114. The first solder pad 112 is positioned and fixed on a center C of the semiconductor chip 114, wherein a size of the first solder pad 112 is smaller than a size of the semiconductor chip 114 to expose a portion of the semiconductor chip 114.

In the embodiment, the semiconductor chip 114 may be connected to the first solder pad 112 with an active surface 114a. The active surface 114a faces away from the first electrode 120. The second solder pad 140 is located between the first electrode 120 and the semi-finished product 110 of the power device. In other words, the first electrode 120, the second solder pad 140, the semiconductor chip 114, the first solder pad 112, and the second electrode 130 may be sequentially stacked, but the disclosure is not limited thereto. In other embodiments, the same may be stacked differently. The second solder pad 140 may be a metallic material. For example, the material of the second solder pad 140 is, for example, tin.

In an embodiment, as shown in FIG. 2A, the first electrode 120 is, for example, a cup-shaped base electrode, which has a bottom surface and a side-wall structure erected on and surrounding the bottom surface, thereby forming a cup-shaped profile. However, the disclosure is not limited thereto. The first electrode 120 may be designed as a base electrode of different forms according to product requirements. The material of the first electrode 120 is, for example, copper, aluminum, or a copper aluminum alloy. The second electrode 130 is, for example, a lead electrode, which is configured to be electrically connected to the first electrode 120. A shape of a bottom of the second electrode 130 connected to the solder pad may be substantially the same as a shape of a corresponding solder pad (for example, the first solder pad 112). For example, the shape of the bottom of the second electrode 130 may be rectangular, circular, or hexagonal, but the disclosure is not limited thereto.

Please refer to FIG. 2B and FIG. 2C at the same time. Then, the first electrode 120, the second electrode 130, the semi-finished product 110 of the power device, and the second solder pad 140 are welded to form an electrical connection. The first electrode 120 and the second electrode 130 are respectively electrode structures of the power device 100, by using the first solder pad 112 and the second solder pad 140, the semiconductor chip 114 is welded therein to be electrically connected to each other, so as to output the inflow of alternating current after being rectified into direct current by the semiconductor chip 114 having rectification function from the power device 100. Here, the first solder pad 112 and the second solder pad 140 shown in FIG. 2A to FIG. 2C are sheet-shaped preforms. After the first solder pad 112 and the second solder pad 140 are assembled and welded as shown in FIG. 2B to FIG. 2C, the semi-finished product 110 of the power device, the second solder pad 140, the first electrode 120, and the second electrode 130 may be physically connected together to achieve the above electrical connection effect. Further, as shown in FIG. 2C, the first solder pad 112 may be sheet-shaped and the active surface 114a of a single sheet of the semiconductor chip 114 is connected to a single sheet of the first solder pad 112. Therefore, the method of the semiconductor chip 114 of the disclosure joining to other devices to be electrically connected to other devices using the first solder pad 112 is different from the method of a conventional chip joining to other devices to be electrically connected to other devices using multiple flip chips.

For example, the first solder pad 112 will melt after welding and extend towards the edge of the semiconductor chip 114. There is a distance between the two edges of the first solder pad 112 and the edge of the semiconductor chip 114. In other words, the first solder pad 112 will not overflow beyond the edge of the semiconductor chip 114 after welding.

Since the semi-finished product 110 of the power device first positions and fixes the first solder pad 112 on the semiconductor chip 114, an offset of the first solder pad 112 by misalignment can be reduced when the first electrode 120, the second electrode 130, the semi-finished product 110 of the power device, and the second solder pad 140 are welded, thereby reducing the probability of overflow after the first solder pad 112 is welded in order to meet the electrical requirements of the power device 100, improve the quality of the power device 100, and increase the yield of the power device 100.

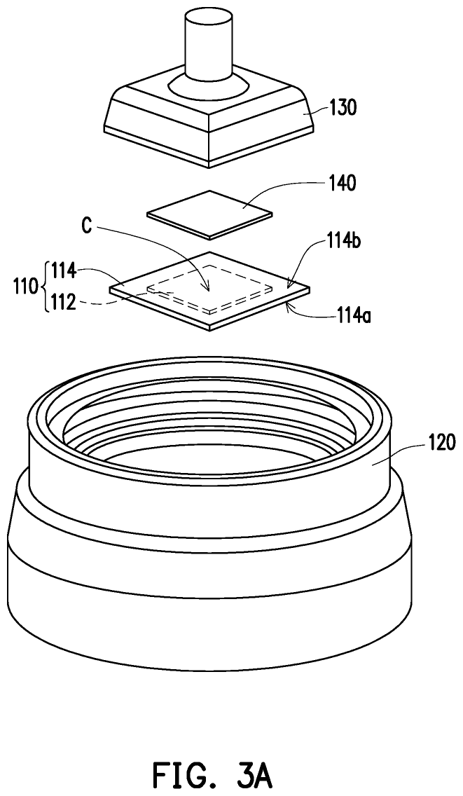

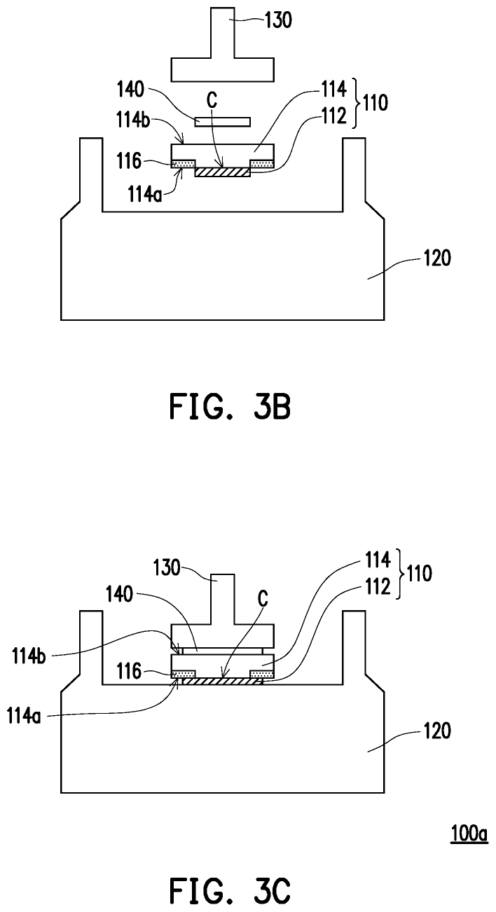

FIG. 3A is a perspective view of a power device according to yet another embodiment of the disclosure. FIG. 3B is a cross-sectional view of a portion of the power device according to FIG. 3A. FIG. 3C is a cross-sectional view of a portion of the power device of FIG. 3B after welding.

Please refer to FIG. 3A to FIG. 3C at the same time. A power device 100a of the embodiment is slightly different from the power device 100 of the previous embodiments. The differences being that an active surface 114a of a semiconductor chip 114 faces a first electrode 120 and a second solder pad 140 is located between a second electrode 130 and a semi-finished product 110 of the power device. In other words, the first electrode 120, the semiconductor chip 114, the first solder pad 112, the second solder pad 140, and the second electrode 130 may be sequentially stacked.

It should be noted that although the semi-finished product 110 of the power device in the foregoing embodiment first positions and fixes the first solder pad 112 on the semiconductor chip 114, in an unshown embodiment, the second solder pad 140 may be first positioned and fixed on a surface of the semiconductor chip 114 opposite to the first solder pad 112 using a method similar to the method of positioning and fixing the first solder pad 112 on the semiconductor chip 114, so as to further reduce the probability of overflow after the second solder pad 140 is welded and also improve the manufacturing efficiency of the power devices 100 and 100a.

In summary, the semi-finished product of the power device of the disclosure, for example, first positions and fixes the first solder pad on the center of the semiconductor chip, so as to reduce the offset of the first solder pad generated by misalignment when the first electrode, the second electrode, and the semi-finished product of the power device, and the second solder pad are welded, thereby reducing the probability of overflow after the first solder pad is welded in order to meet the electrical requirements required by the power device, improve the quality of the power device, and increase the yield of the power device. In addition, in order to reduce the situation of overflow causing short-circuit after the solder pad on the active surface of the semiconductor chip is welded, the semi-finished product of the power device of the disclosure may first position and fix the first solder pad on the active surface of the semiconductor chip before performing the subsequent process, so as to further improve the quality of the power device and the yield of the power device.

Although the disclosure has been disclosed in the above embodiments, the embodiments are not intended to limit the disclosure. It will be apparent to persons skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A semi-finished product of a power device, comprising:
a semiconductor chip, having an active surface and a rear surface opposite to the active surface; and
a first solder pad, positioned and fixed on a center of the semiconductor chip, wherein the first solder pad is sheet-shaped, the semiconductor chip is connected to the first solder pad by the active surface, and a size of the first solder pad is smaller than a size of the semiconductor chip to expose a portion of the semiconductor chip.

2. The semi-finished product of the power device according to claim 1, wherein distances between two opposite edges of the first solder pad and the center are substantially equal, and a ratio of a surface area of the active surface occupied by the first solder pad is between 50% and 70%.

3. The semi-finished product of the power device according to claim 1, wherein the semiconductor chip comprises an insulating portion, the insulating portion surrounds the first solder pad, and the active surface of a single sheet of the semiconductor chip is connected to a single sheet of the first solder pad.

4. A manufacturing method of a semi-finished product of a power device, comprising:
providing a mold, wherein the mold has a plurality of grooves;
disposing a first solder pad in at least one of the plurality of grooves;
disposing a semiconductor chip on the first solder pad, wherein the first solder pad is positioned on a center of the semiconductor chip, and a size of the first solder pad is smaller than a size of the semiconductor chip to expose a portion of the semiconductor chip;
fixing the first solder pad on the center; and
removing the mold.

5. The manufacturing method of the semi-finished product of the power device according to claim 4, wherein the semiconductor chip has an active surface and a rear surface opposite to the active surface, the semiconductor chip is connected to the first solder pad with the active surface, and the step of fixing the first solder pad on the center comprises:
sintering the first solder pad and the semiconductor chip, such that the first solder pad is fixed on a center of the active surface.

6. The manufacturing method of the semi-finished product of the power device according to claim 5, wherein:
before the step of fixing the first solder pad on the center, the method further comprises disposing a second solder pad on the rear surface; and
the step of fixing the first solder pad on the center comprises sintering the first solder pad, the second solder pad, and the semiconductor chip to fix the first solder pad and the second solder pad to the semiconductor chip.

7. A manufacturing method of a power device, comprising:
providing a semi-finished product of a power device, a first electrode, a second electrode, and a second solder pad, wherein the semi-finished product of the power device and the second solder pad are located between the first electrode and the second electrode, and the semi-finished product of the power device comprises:
a semiconductor chip; and
a first solder pad, positioned and fixed on a center of the semiconductor chip, wherein a size of the first solder pad is smaller than a size of the semiconductor chip to expose a portion of the semiconductor chip; and
welding the first electrode, the second electrode, the semi-finished product of the power device, and the second solder pad to form an electrical connection.

8. The manufacturing method of the power device according to claim 7, wherein the semiconductor chip has an active surface and a rear surface opposite to the active surface, the semiconductor chip is connected to the first solder pad with the active surface, the active surface faces away from the first electrode, and the second solder pad is located between the first electrode and the semi-finished product of the power device.

9. The manufacturing method of the power device according to claim 7, wherein the semiconductor chip has an active surface and a rear surface opposite to the active surface, the semiconductor chip is connected to the first solder pad with the active surface, the active surface faces the first electrode, and the second electrode is located between the second electrode and the semi-finished product of the power device.

10. The manufacturing method of the power device according to claim 7, wherein the power device is a rectifier diode apparatus, the first electrode is a base electrode of the rectifier diode apparatus, and the second electrode is a lead electrode of the rectifier diode apparatus.

11. The manufacturing method of the power device according to claim 8, wherein the power device is a rectifier diode apparatus, the first electrode is a base electrode of the rectifier diode apparatus, and the second electrode is a lead electrode of the rectifier diode apparatus.

12. The manufacturing method of the power device according to claim 9, wherein the power device is a rectifier diode apparatus, the first electrode is a base electrode of the rectifier diode apparatus, and the second electrode is a lead electrode of the rectifier diode apparatus.
